(19) United States
(12) Patent Application Publication
(10) Pub. No.: US 2004/0000730 A1
(43) Pub. Date: Jan. 1, 2004

(54) Compensating light source capable of compensating for a light intensity attenuation caused by the optical path and designing method

(76) Inventors: Kuan-Yu Lee, Taichung (TW); Chen-Hsiang Shih, Changhua (TW)

Correspondence Address: BIRCH STEWART KOLASCH & BIRCH, PO BOX 747, FALLS CHURCH, VA, 22040-0747, US

(21) Appl. No.: 10/449,077

(22) Filed: Jun. 2, 2003

(30) Foreign Application Priority Data
Jun. 13, 2002 (TW) 091112968

(51) Int. Cl. H01L 31/109

(52) U.S. Cl. 257/E27.132; 382/237

(57) ABSTRACT

A compensating light source capable of compensating for the light intensity attenuation caused by the optical path and the designing method. First, a number of the predetermined light sources, which have uniform luminance, are chosen to respectively illuminate a chart with a uniform gray scale and produce a number of scanning light beams with respect to these predetermined light sources. After that, the scanning light beams are collected and focused to form an image on the optical sensing devices with respect to a number of image pixels. These image pixels can produce a number of sensing voltages with respect to the predetermined light sources. The tube dimensions of these predetermined light sources are relative to the sensing voltages of the predetermined light sources to form relative data. The relative data and the sensing voltages with respect to the selected predetermined light source are used to design a compensating light source. Then, a check action is performed.

This application claims the benefit of Taiwan application Serial No. 91112968, filed Jun. 13, 2002.

### BACKGROUND OF THE INVENTION

1. Field of the Invention

This invention relates to a light source and, more particularly, the invention relates to a compensating light source capable of compensating for the light intensity attenuation caused by the optical path and the designing method.

2. Description of Related Art

Referring to FIG. 1, it is a drawing, schematically illustrating a conventional scanner 100 to scan a chart 110 with a uniform gray scale. As shown in FIG. 1, the scanner 100 at least includes a chassis 101. The chassis 101 is used to scan a chart 110 with a uniform gray scale on a scanning platform (not shown in FIG. 1) of the scanner 100. The chassis 101 includes a cold cathode fluorescent lamp (CCFL) 102 with uniform tube diameter and uniform luminance, reflection mirror 104, the lens 106, and a charge coupled device (CCD) 108 with a number of pixels.

When the chassis 101 scans a chart 110 with a uniform gray scale, the cold cathode fluorescent lamp 102 then provides a uniform light to illuminate the chart 110 with the uniform gray scale. Then, the chart 110 with the uniform gray scale reflects the light provided by the cold cathode fluorescent lamp 102, so as to produce a scanning light beam 112. The reflection mirror 104 then reflects the scanning light beam 112, so as to allow the lens 106 to collect the scanning light beam 112. Then, the light is focused to form the image on the CCD 108, in which each one of the image pixels respectively has a sensing voltage. After all of the sensing voltage has been collected and then been converted into image data, the scanner 100 will obtain a complete image picture of the chart 110 with the uniform gray scale. In addition, the sensing voltage produced at each one of the image pixels of the CCD 108 is proportional to the light intensity received by the corresponding pixels.

Referring to FIG. 2, it is a drawing, schematically illustrating an optical path among the chart with the uniform gray scale, the lens, and the CCD. As shown in FIG. 2, it is assumed that the CCD 108 has a number of pixels by 2N, which are sequentially indicated by (1), (2), . . . , (N), . . . , . . . (2N), and the value of N is a positive integer. In the sequence of forming the image, the light beam reflected by the two sides of the chart 110 with the uniform gray scale has the length of the optical paths 114a and 114c, and the optical paths 114a and 114c are longer than the length of the optical path 114b of the light reflected by the chart 110 with the uniform gray scale from the central region. Further still, since the light intensity is also inversely proportional to the square of the length of the optical path, the degree of the portional to the square of the length of the optical path, the degree of the light intensity attenuation occurring on the optical paths 114a and 114c is greater than the light intensity attenuation occurring on the optical path 114b. Therefore, when pixels (1) and (2N) at the two sides of the CCD 108 are respectively receiving the light beams on the optical paths 114a and 114c, the pixels (1) and (2N) will respectively obtain the sensing voltages A and C, as shown in FIG. 3. Likewise, when the pixel (N) at the central region of the CCD 108 receives the light beam on the optical path 114b, the pixel (N) will obtain the sensing voltage B. Since the optical path in the central region is shorter than the optical paths on the two sides, the quantity of the sensing voltage B will be greater than the quantities of the sensing voltages A and C. This will result in a relative curve for the pixels in FIG. 3, and the sensing voltage becomes a curved line that opens downward.

It should be noted that the entire chart has a uniform gray scale, and in the case that the light intensity attenuation does not occur, each one of the pixels of the CCD, theoretically, should obtain the same sensing voltage, as shown in FIG. 3, to be the horizontal line formed between the pixels and the sensing voltage .

Thus, due to light intensity attenuation caused by the different optical paths, a phenomenon will occur causing the pixels of the CCD for the chart with the uniform gray scale to have higher sensing voltage with respect to the central region and lower sensing voltage with respect to the two sides. This can cause the image obtained by the scanner to have a color bias. This greatly affects the quality of the scanning operation. If the user does not resolve this issue and continuously uses the scanner to scan other documents, it will result in a serious situation in which image fidelity is lost.

### SUMMARY OF THE INVENTION

It is therefore an objective of the present invention to provide a compensating light source capable of compensating for the light intensity attenuation caused by the optical path and the designing method. The present invention uses a cold cathode fluorescent lamp with a different tube diameter to produce different luminance under the same current. A light tube is formed with smaller diameter at the two ends and a larger diameter at the central region. As a result, the two ends of the light tube are brighter than the central region of the light tube, so as to achieve the objective of compensating for the light intensity attenuation caused by the different optical path.

In accordance with the foregoing and other objectives of the present invention, the invention provides a designing method for a compensating light source capable of compensating for the light intensity attenuation caused by the optical path. At first, a number of the predetermined light sources, which have uniform luminance, are chosen to respectively illuminate a chart with a uniform gray scale and produce a number of scanning light beams with respect to these predetermined light sources. Wherein, these predetermined light sources have different tube diameters. The scanning light beams are then collected and focused to form an image on the optical sensing devices with a number of image pixels. These image pixels produce a number of sensing voltages with respect to the predetermined light sources. The tube diameters of these predetermined light sources and the sensing voltages with respect to the predetermined light sources form relative data. The relative data and sensing voltages with respect to one of the predetermined light sources are then used to design a compensating light source. The compensating light source is then checked to see if it satisfies the specification. If it does not, another compensating light source is redesigned.

Wherein, the compensating light source includes a first light emitting part and a second light emitting part, in which the second light emitting part is located at two ends of the first light emitting part. The size of the tube diameter of the second light emitting part is smaller than the size of the tube diameter of the first light emitting part. The luminance of the second light emitting part is greater than the luminance of the first light emitting part.

### BRIEF DESCRIPTION OF DRAWINGS

The invention can be more fully understood by reading the following detailed description of the preferred embodiments, with reference made to the accompanying drawings, wherein:

FIG. 1 is a drawing, schematically illustrating a conventional scanner to scan a chart with a uniform gray scale;

FIG. 2 is a drawing, schematically illustrating an optical path among the chart with the uniform gray scale, the lens, and the CCD as shown in FIG. 1;

FIG. 3 is a relative curve in rectangular coordinates between each one of the image pixels of the charge coupled device in FIG. 2 and sensing voltages obtained;

FIG. 4 is a flow diagram, schematically illustrating the process to design the compensating light source capable of compensating for the light intensity attenuation caused by the optical path, according to the embodiment of the present invention;

FIG. 5 is a drawing, schematically illustrating a side view of the cold cathode fluorescent lamp, which has uniform tube diameter and uniform luminance;

FIG. 6 is a drawing, schematically illustrating a side view of the cold cathode fluorescent lamp, which is capable of compensating for the light intensity attenuation due to the optical path and then has a smaller diameter at the two ends as well as a larger diameter at the central region, according to the embodiment of the present invention; and

FIG. 7 is a relative curve in rectangular coordinates between each one of the image pixels of the charge coupled device to produce the same sensing voltages.

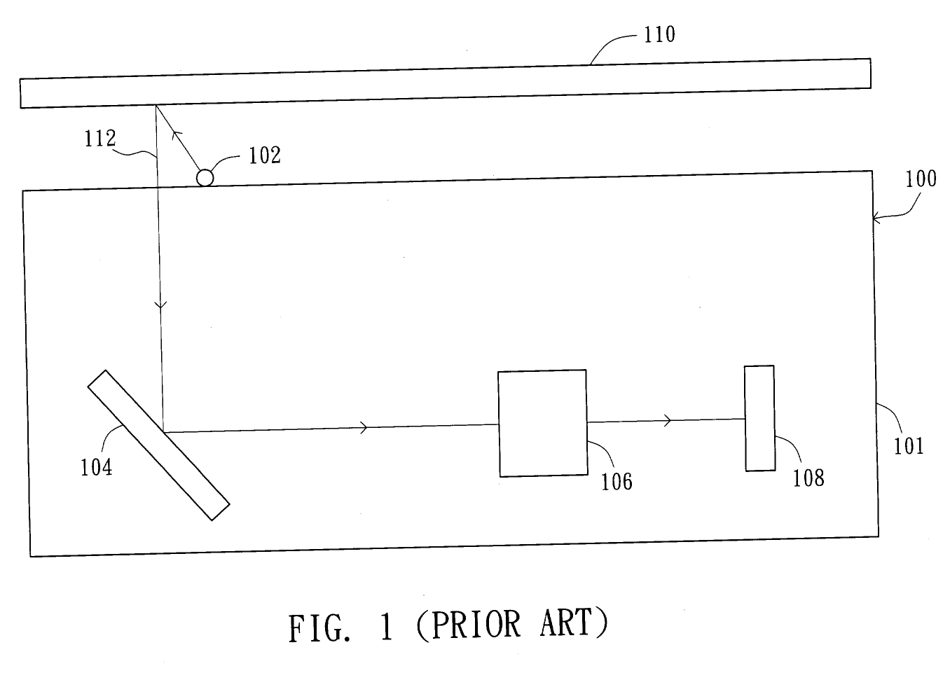

### DETAILED DESCRIPTION OF PREFERRED EMBODIMENTS

The present invention provides a compensating light source capable of compensating for the light intensity attenuation caused by the optical path and the designing method. The present invention uses a cold cathode fluorescent lamp with different tube diameter to produce different luminance under the same current. A light tube is formed with a smaller diameter at the two ends and a larger diameter at the central region. As a result, the light emitted from two ends of the light tube is brighter than the light emitted from the central region of the light tube, so as to achieve the objective of compensating for the light intensity attenuation caused by the different optical path.

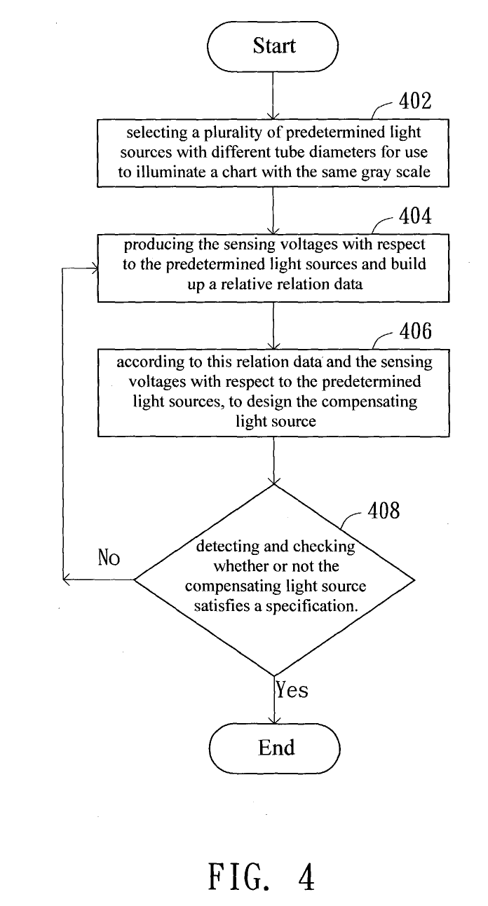

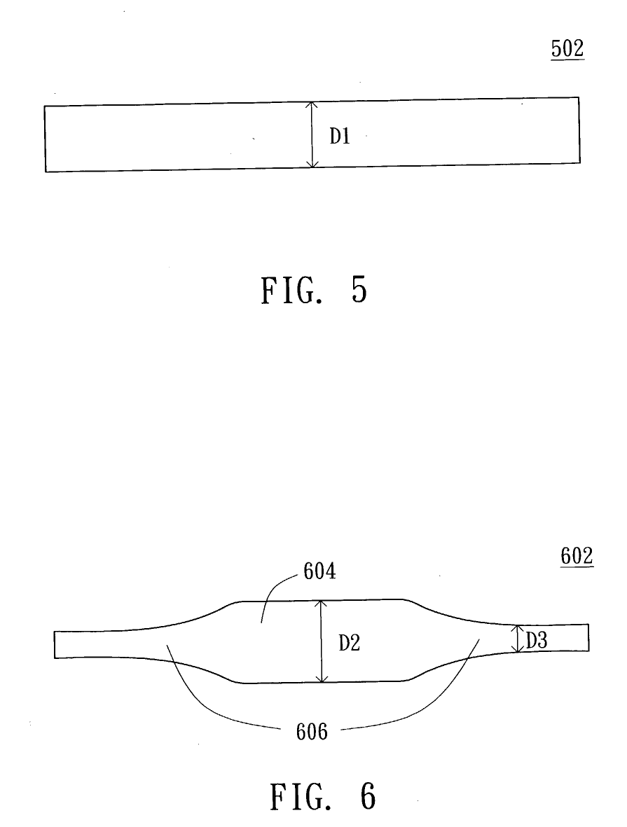

FIG. 4 is a flow diagram, schematically illustrating the process to design the compensating light source capable of compensating for the light intensity attenuation caused by the optical path, according to the embodiment of the present invention. As shown in FIG. 4, at first in step 402, a number of the predetermined light sources, which have uniform luminance, are chosen to respectively illuminate a chart with a uniform gray scale and produce a number of scanning light beams with respect to these predetermined light sources. Wherein, these predetermined light sources have different tube diameters. In addition, the chart with a uniform gray scale can be a chart with whole black or whole white. Further still, the present invention can use a cold cathode fluorescent lamp 502 with uniform tube diameter and uniform luminance, as shown in FIG. 5. Also, the cold cathode fluorescent lamp 502 has a uniform tube diameter D1.

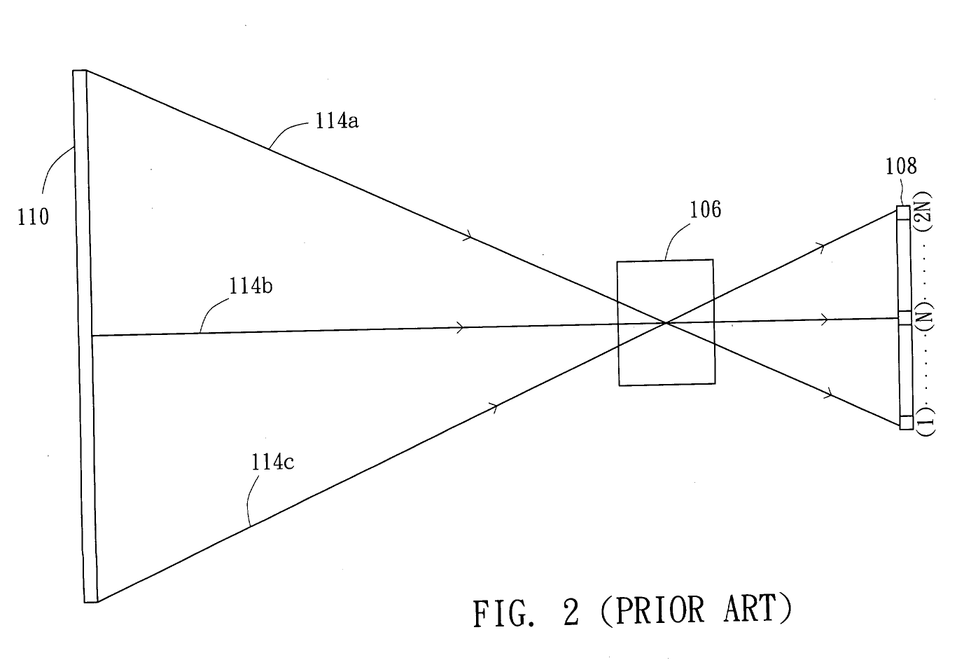

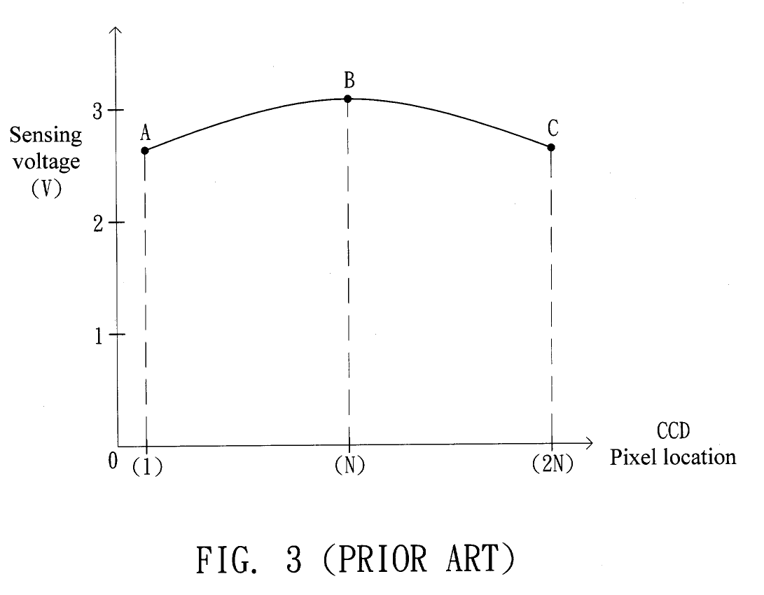

Then, the process enters step 404, in which step a lens is used to collect each of the scanning light beams and focuses them to form an image on the optical sensing device with a number of image pixels. Due to light intensity attenuation caused by the optical path, these image pixels will produce a number of sensing voltages with respect to each of the predetermined light sources. Further, the tube dimensions of these predetermined light sources and the sensing voltages with respect to the predetermined light sources form relative data. For example, the optical sensing devices can include a charge coupled device (CCD), and the CCD has the number of the image pixels by 2N, in which the pixels are sequentially indicated by (1), (2), . . . , (N), . . . , . . . (2N), and the value of N is a positive integer. As shown in FIG. 2, since the light intensity is inversely proportional to the square of the optical length, after the 2N number of the image pixels receives the light beams from the different optical paths, the 2N number of the image pixels will produce the different sensing voltages.

Taking the cold cathode fluorescent lamp as an example, the ultraviolet light generated by the mercury inside the lamp is converted by the fluorescent powder coated on the inner wall of the lamp into the visible light. However, on the path from the point at which the ultraviolet light is generated to the arrival point on the wall of the lamp, a portion of the ultraviolet light will be absorbed again by the other mercury atoms. The amount of loss is proportional to the lamp tube diameter. In other words, when the tube diameter of the cold cathode fluorescent lamp is larger, the distance from the point at which the ultraviolet light is generated to the fluorescent coating layer becomes longer. The possibility for the ultraviolet being absorbed again before arriving at the lamp wall is also increased. Therefore, when loss due to the absorption increases, the luminance of the lamp with the larger diameter will be less than the luminance of the lamp with the smaller diameter. This means that the luminance is inversely proportional to the tube diameter of the lamp. The luminance of the lamp is also proportional to the sensing voltages with respect to the sensing voltages generated by the corresponding optical sensing devices.

In addition, the present invention can provide the same current quantity to the predetermined light sources with different tube diameter, so as to obtain the sensing voltage generated by the corresponding optical sensing devices accordingly. After the collection of all of the information, the present invention has found that the tube diameters of the predetermined light sources are related to the sensing voltages correspondingly generated by the predetermined light sources, and the relative data are formed. This also means that the sensing voltages are inversely proportional to the tube diameter of the predetermined light sources. This relative data can be used as the design principle for the compensating light source.

Then, entering into step 406, according to the relative data formed form the basis of the sensing voltages and the tube diameters of the predetermined light sources and the sensing voltages of any one of the predetermined light sources, a compensating light source is designed, so as to compensate for the light intensity attenuation caused by the optical path.

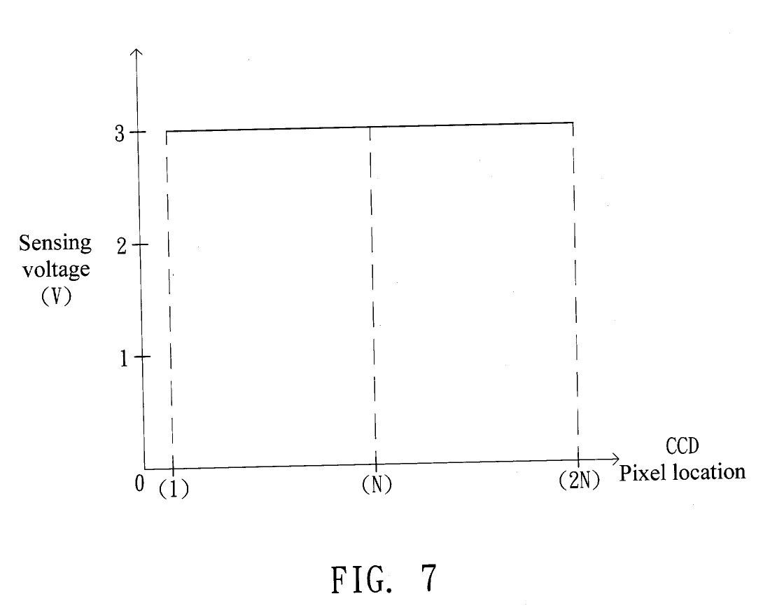

Thus, the present invention designs a lamp tube with a smaller diameter at the two end portions and a larger diameter at the central portion. As shown in FIG. 6, the cold cathode fluorescent lamp 602 has the light emitting portions 604 and 606. The light emitting portion 606 is located at the two ends of the light emitting portion 604, and the tube diameter D2 of the light emitting portion 604 is larger than the tube diameter D3 of the light emitting portion 606. In this manner, the luminance of the light emitting portion 606 of the cold cathode fluorescent lamp 602 is greater than the luminance of the light emitting portion 604. As a result, the cold cathode fluorescent lamp 602 then can compensate for the light intensity attenuation caused by the optical path, so that when the chart with the uniform gray scale is scanned, each one of the image pixels of the optical sensing device can produce the same level of sensing voltages, as shown in FIG. 7.

In step 408, the compensating light source is checked to see whether or not it satisfies the specification. If it does, the method is completed. If it does not, another compensating light source is designed again. For example, the compensating light source designed in the step 406 is used to illuminate the chart with the uniform gray scale, so as to judge whether or not the image pixels have a tendency to produce the same level of sensing voltage. If it does, then the method is completed. If it does not, then the method goes back to step 404. The image pixels of the CCD will produce a few more sensing voltages with respect to the compensating light source, so as to design another compensating light source. An oscilloscope or software tool can also be used with the present invention to examine the compensating light source to see whether or not it satisfies the required specification.

In summary, the foregoing embodiment disclosed by the present invention regarding the compensating light source capable of compensating for the light intensity attenuation caused by the optical path and the designing method by using the cold cathode fluorescent lamp with different tube diameters, so as to produce the different luminance under conditions with the same lamp current. The tube lamp has a smaller tube diameter at the two end portions and a larger tube diameter at the central portion. As a result, the light emitted form the two end portions is brighter than light emitted form the central portion, so as to achieve the objective of compensating for the light intensity attenuation caused by the optical path.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A designing method for a compensating light source, capable of compensating for light intensity attenuation caused by an optical path, the method comprising:
selecting a plurality of predetermined light sources, which have a uniform luminance, for use to respectively illuminate a chart with a uniform gray scale and produce a plurality of scanning light beams with respect to the predetermined light sources, wherein the predetermined light sources respectively have different tube diameters;
collecting the scanning light beams and focusing to form an image on an optical sensing device, which has a plurality of image pixels, and the image pixels produce a plurality of sensing voltages with respect to the predetermined light sources, and the tube diameters of the predetermined light sources are related to the sensing voltages with respect to the predetermined light sources, so as to build up relative data;
using the relative data and the sensing voltages with respect to one of the predetermined light sources, so as to design the compensating light source; and
detecting and checking whether or not the compensating light source satisfies a specification; if it does not then another compensating light source is designed.

2. The method as recited in claim 1, wherein the step of detecting and checking whether or not the compensating light source satisfies the specification further comprises:
using the compensating light source to illuminate the chart with the uniform gray scale, so as to detect and check whether or not the compensating light source satisfies the specification, and if it does not then a plurality of other sensing voltages with respect to the compensating light source are produced by the image pixels and another compensating light source is designed.

3. The method as recited in claim 1, wherein the step of detecting and checking whether or not the compensating light source satisfies the specification further comprises:
using an oscilloscope to detect and check whether or not the compensating light source satisfies the specification, and if it does not then another compensating light source is designed.

4. The method as recited in claim 1, wherein the step of detecting and checking whether or not the compensating light source satisfies the specification further comprises:
using a software tool to detect and check whether or not the compensating light source satisfies the specification, and if it does not then another compensating light source is designed.

5. The method as recited in claim 1, wherein the predetermined light source includes a cold cathode fluorescent lamp (CCFL).

6. The method as recited in claim 1, wherein the compensating light source includes a cold cathode fluorescent lamp.

7. The method as recited in claim 1, wherein the compensating light source includes:
a first light emitting portion; and
a second light emitting portion, located at two ends of the first light emitting portion, wherein the tube diameter of the second light emitting portion is smaller than the tube diameter of the first light emitting portion, also and the luminance of the second light emitting portion is greater than the luminance of the first light emitting portion.

8. The method as recited in claim 1, wherein the relative data has shown that the tube diameters of the predetermined light sources are inversely proportional to the sensing voltages with respect to the predetermined light sources.

9. The method as recited in claim 1, wherein the optical sensing device includes a charge coupled device (CCD).

10. The method as recited in claim 1, wherein the step of collecting the scanning light beams further comprises:
using a lens to collect all of the scanning light beams, and focusing them to form an image on the optical sensing device.

11. A designing method for a compensating light source, capable of compensating for light intensity attenuation caused by an optical path, the method comprising:
selecting a plurality of cold cathode fluorescent lamps, which have a uniform luminance, for use to respectively illuminate a chart with a uniform gray scale and produce a plurality of scanning light beams with respect to the cold cathode fluorescent lamps, wherein the cold cathode fluorescent lamps have different tube diameters;
using a lens to collect the scanning light beams and focusing them to form an image on a charge coupled device, which has a plurality of image pixels, and the image pixels produce a plurality of sensing voltages with respect to the cold cathode fluorescent lamps, and the tube diameters of the cold cathode fluorescent lamps are related to the sensing voltages with respect to the predetermined light sources, so as to build up relative data;
using the relative data and the sensing voltages with respect to one of the cold cathode fluorescent lamps, so as to design the compensating light source; and
using the compensating light source to illuminate the chart with the uniform gray scale, so as to detect and check whether or not the compensating light source satisfies the specification, and if it does not then a plurality of other sensing voltages with respect to the compensating light source are produced by the image pixels and another compensating light source is designed.

12. The method as recited in claim 11, wherein the compensating light source includes a cold cathode fluorescent lamp.

13. The method as recited in claim 11, wherein the compensating light source includes:
a first light emitting portion; and
a second light emitting portion, located at two ends of the first light emitting portion, wherein the tube diameter of the second light emitting portion is smaller than the tube diameter of the first light emitting portion, and a luminance of the second light emitting portion is greater than a luminance of the first light emitting portion.

14. The method as recited in claim 11, wherein the relative data has shown that the tube diameters of the predetermined light sources are inversely proportional to the sensing voltages with respect to the predetermined light sources.

15. A designing method for a compensating light source, capable of compensating for light intensity attenuation caused by an optical path, the method comprising:
selecting a plurality of cold cathode fluorescent lamps, which have a uniform luminance, for use to respectively illuminate a chart with a uniform gray scale and produce a plurality of scanning light beams with respect to the cold cathode fluorescent lamps, wherein the cold cathode fluorescent lamps respectively have different tube diameters;
using a lens to collect the scanning light beams and focusing them to form an image on a charge coupled device, which has a plurality of image pixels, and the image pixels produce a plurality of sensing voltages with respect to the cold cathode fluorescent lamps, and the tube diameters of the cold cathode fluorescent lamps are related to the sensing voltages of the predetermined light sources, so as to build up relative data; and
using the relative data and the corresponding sensing voltages with respect to one of the cold cathode fluorescent lamps, so as to design the compensating light source, wherein the compensating light source comprises a first light emitting portion and a second light emitting portion, wherein the second light emitting portion is located at two ends of the first light emitting portion, wherein the tube diameter of the second light emitting portion is smaller than the tube diameter of the first light emitting portion, also and the luminance of the second light emitting portion is greater than a luminance of the first light emitting portion.

16. The method as recited in claim 15, wherein the relative data has shown that the tube diameters of the predetermined light sources are inversely proportional to the sensing voltages with respect to the predetermined light sources.

17. A compensating light source, comprising:
a first light emitting portion; and
a second light emitting portion, located at two ends of the first light emitting portion, wherein the tube diameter of the second light emitting portion is smaller than the tube diameter of the first light emitting portion, and the luminance of the second light emitting portion is greater than the luminance of the first light emitting portion.
